(19) United States
(12) Patent Application Publication
(10) Pub. No.: US 2024/0248192 A1
(43) Pub. Date: Jul. 25, 2024

(54) RADAR CIRCUIT

(71) Applicant: VEGA Grieshaber KG, Wolfach (DE)

(72) Inventors: Daniel SCHULTHEISS, Hornberg (DE); Roland WELLE, Hausach (DE); Christoph MUELLER, Oppenau (DE)

(73) Assignee: VEGA Grieshaber KG, Wolfach (DE)

(21) Appl. No.: 18/420,504

(22) Filed: Jan. 23, 2024

(30) Foreign Application Priority Data
Jan. 23, 2023 (DE) 10 2023 101 551.6

(51) Int. Cl. G01S 13/42; G06F 9/448; H02M 7/155; H03L 7/081

(52) U.S. Cl. CPC G01S 13/42; G06F 9/4498; H02M 7/1555; H03L 7/0812

(57) ABSTRACT

A radar circuit for a measuring device is provided, including: a radar chip, configured to generate a radar measurement signal; an application-specific integrated circuit (ASIC); and a processor, configured to determine a measured value, the ASIC and the radar chip being separate components.

### CROSS-REFERENCE TO RELATED APPLICATIONS

This application claims the benefit of priority under 35 U.S.C. § 119 from German Patent Application No. 10 2023 101 551.6 filed on 23 Jan. 2023, the entire content of which is incorporated herein by reference.

### TECHNICAL FIELD

The present invention relates to measuring device technology for process automation in industrial and private environments. In particular, the invention relates to a radar circuit for a measuring device and the use of an application-specific integrated circuit for a measuring device, in particular for a level radar measuring device.

### BACKGROUND

Measuring devices for process automation in industrial and private environments can have radar circuits that generate a radar measurement signal, which is then emitted via a corresponding antenna. Examples of such measuring devices are radar level measuring devices that can be installed in a container. These radar level gauges can be free-radiating or use the guided wave principle. In the latter case, an elongated measuring probe is provided which is immersed in the product.

Such measuring devices often have a limited energy supply, for example in the form of a 4 to 20 mA two-wire line or, particularly in the case of a stand-alone measuring device, in the form of an internal energy storage device such as a battery. To reduce the energy requirement of such a measuring device, the frequency of measurements can be reduced. Level changes during measurement pauses are only recorded at a later point in time.

### SUMMARY

There may be a desire to provide a radar circuit for a measuring device which enables energy-efficient operation even with smaller measuring pauses.

This desire is met by the subject-matter of the independent patent claims. Further embodiments of the present disclosure result from the subclaims and the following description of embodiments.

A first aspect of the present disclosure relates to a radar circuit for a measuring device comprising a radar chip, an application specific integrated circuit (ASIC) and a processor.

The measuring device is, for example, a level measuring device, in particular a level radar measuring device, or another radar measuring device.

The radar chip is configured to generate a radar measurement signal, which is then emitted by an antenna or a radiating element. The processor is configured to determine a measured value from the radar signals received. The ASIC and the radar chip are separate components and are interconnected via corresponding control and supply lines.

The ASIC can be designed as a radar companion ASIC, which performs control tasks and/or measured value acquisition tasks in the radar circuit. In this way, essential control and detection tasks may be combined in a compact unit at low cost when using different radar chips, while at the same time enabling energy-efficient operation of the corresponding radar chip.

According to one embodiment, the ASIC has a phase-locked loop (PLL).

According to a further embodiment, the ASIC has an analog-to-digital converter circuit (ADC).

According to a further embodiment, the ASIC has a digital interface to the processor.

According to a further embodiment, the ASIC has a finite state machine (FSM) which is set up to control the radar chip.

According to a further embodiment, the radar chip is a radar monolythic microwave integrated circuit (MMIC).

According to a further embodiment, the radar circuit is a level radar circuit for a level radar measuring device.

According to a further embodiment, the ASIC is configured to wake the processor from a sleep mode and then transmit measurement data to the processor.

According to a further embodiment, the ASIC is configured to supply a voltage-controlled oscillator (VCO) of the radar chip and/or a multiplier of the radar chip.

PLL, ADC, power management, and safety functions may all be integrated on the ASIC. In particular, the ASIC may be configured to support different radar chips with different operating frequencies, for example 6 GHz, 24 GHz, 80 GHz, 180 GHz, and 240 GHz. To achieve this, the finite state machine can be programmed accordingly.

The radar chip and the ASIC may be optimized with regard to the energy requirement for detecting an echo curve. In particular, it may be provided that parts of the radar chip, the ASIC and/or the processor are only switched on when they are actually needed. Circuit parts that are not required may be switched off quickly. In particular, the radar circuit may be optimized in terms of size and cost.

In particular, the radar circuit may be configured to be supplied from a limited energy source (e.g., 4 to 20 mA supply or energy harvesting). A supply voltage of 3.3 V can be provided, both for the processor and for the ASIC. The ASIC may also be configured for several different supply voltages. The ASIC and the radar chip can be positioned on the same PCB.

The radar circuit and in particular the ASIC may be configured in such a way that the measurement sequence and the determination of the measured value can be operated in an energy-saving operating mode that is dependent on the radar chip used. In particular, it may be provided that the ASIC is configured to control an activation sequence suitable for the connected radar chip, for example by activating individual or several of the supply voltages of the radar chip in a time- and/or energy-optimized manner. It may be provided that the ASIC generates at least one or more of the supply voltages of the radar chip internally and forwards them to the radar chip. It may further be provided that the ASIC generates and provides signals which cause the radar chip to perform a radar measurement, whereby the signals detected by the radar chip can be digitized by the ASIC essentially simultaneously and further processed internally, for example by internally storing digitized samples of the analog signals of the radar chip. It is possible that during this time sequence of data acquisition by the radar chip and the ASIC, the processor does not provide any control signals and is put into a sleep state, for example. Furthermore, it may be provided that the ASIC is set up to control a deactivation sequence of the connected radar chip, for example by deactivating individual or several of the supply voltages of the radar chip in a time and/or energy-optimized manner.

As already explained above, the radar companion ASIC may comprise a PLL, at least one ADC, a digital interface to a processor, a state machine for controlling the radar MMIC, whereby the state machine is set up to optimize the operation of the MMIC with regard to its energy consumption and/or with regard to compliance with spectral radiation characteristics for radio approvals.

A further aspect of the present disclosure relates to the use of an ASIC described above and below for a measuring device, in particular for a level measuring device comprising a radar chip, wherein the ASIC and the radar chip are separate components.

The term “process automation in an industrial environment” may be understood as a branch of technology that includes measures for the operation of machines and systems without the involvement of humans. One aim of process automation is to automate the interaction of individual components of a plant in the chemical, food, pharmaceutical, petroleum, paper, cement, shipping, or mining industries. A variety of sensors can be used for this purpose, which are adapted in particular to the specific requirements of the process industry, such as mechanical stability, insensitivity to contamination, extreme temperatures, and extreme pressures. Measured values from these sensors are usually transmitted to a control room, where process parameters such as fill level, limit level, flow rate, pressure, or density can be monitored and settings for the entire plant can be changed manually or automatically.

One area of process automation in the industrial environment concerns the logistics automation of systems and the logistics automation of supply chains. Distance and angle sensors are used in logistics automation to automate processes inside or outside a building or within an individual logistics system. Typical applications for logistics automation systems include baggage and freight handling at airports, traffic monitoring (toll systems), retail, parcel distribution, and building security (access control). What the examples listed above have in common is that presence detection in combination with precise measurement of the size and position of an object is required by the respective application. Sensors based on optical measurement methods using lasers, LEDs, 2D cameras, or 3D cameras, which detect distances according to the time-of-flight (ToF) principle, can be used for this purpose.

Another area of process automation in the industrial environment is factory/production automation. Applications for this can be found in a wide variety of sectors such as automotive manufacturing, food production, the pharmaceutical industry, or in the packaging sector in general. The aim of factory automation is to automate the production of goods using machines, production lines and/or robots, i.e., to run them without human intervention. The sensors used here and the specific requirements in terms of measuring accuracy when detecting the position and size of an object are comparable to those in the previous example of logistics automation.

### BRIEF DESCRIPTION OF THE FIGURES

In the following, embodiments of the present disclosure are described with reference to the figures. If the same reference signs are used in the following description of the figures, these designate the same or similar elements. The illustrations in the figures are schematic and not to scale.

FIG. 1 shows a circuit diagram of a radar MMIC with a peripheral circuit using discrete components;

FIG. 2 shows a radar companion ASIC that can take over control and detection tasks when operating a purely analog MMIC;

FIG. 3 shows the structure of a radar circuit for a radar measuring device with the ASIC of FIG. 2;

FIG. 4 illustrates the universal usability of the Radar Companion ASIC for widely used radar MMICs for level measurement;

FIG. 5 shows the time sequence for energy-optimized recording of measured values;

FIG. 6 shows an example of the states of a processor during the energy-optimized acquisition of measured values;

FIG. 7 shows an example of the states of a Radar Companion ASIC during the energy-optimized acquisition of measured values; and

FIG. 8 shows a measuring device with a radar circuit.

### DETAILED DESCRIPTION OF EMBODIMENTS

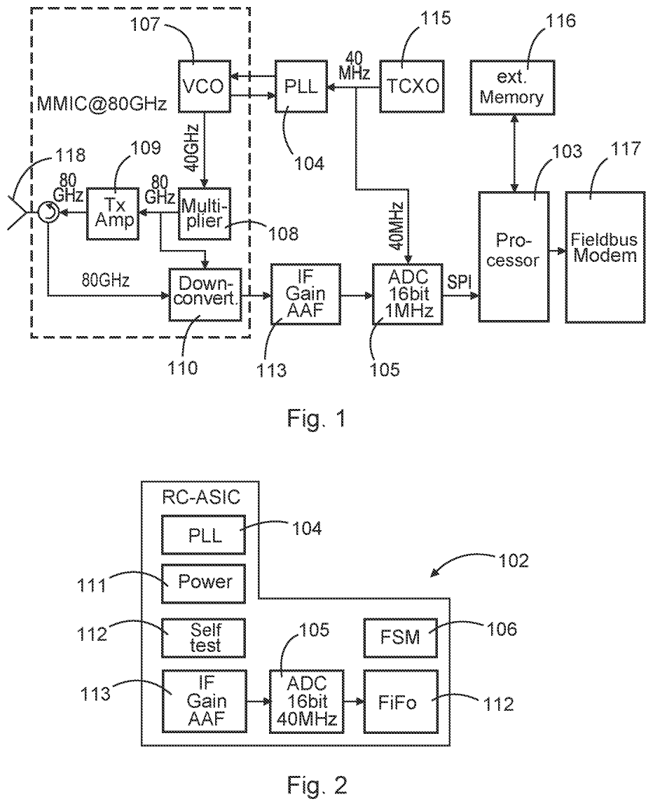

FIG. 1 shows a radar MMIC 101 with a peripheral circuit using discrete components. The radar MMIC 101 generates a radar measurement signal of 80 GHz, which is emitted via the antenna 118 in the direction of the product. The MMIC 101 has a VCO 107, which is controlled by an external PLL 104. A temperature-compensated crystal oscillator (TCXO) 115 is provided, which controls the PLL with a frequency of 40 MHz. The TCXO also controls the ADC circuit 105.

In addition to the VCO 107, the MMIC 101 has a multiplier 108, which is controlled by the VCO 107 at 40 GHz. The multiplier doubles the frequency to 80 GHz and controls a TX amplifier 109, which is connected to the antenna 118 via a transmit/receive switch, for example a circulator. In addition, a down converter or mixer 110 is provided, which receives signals from the multiplier 108 and the transmit/receive switch.

All other components are located outside the MMIC 101. The down converter 110 passes its signal to an analog amplifier and filter circuit 113, which then passes it on to the ADC circuit 105. The ADC circuit 105 is connected to the processor 103 via a serial peripheral interface (SPI), for example. The processor 103 can exchange data with an external memory 116. In addition, the processor 103 is connected to a fieldbus modem 117 for measured value transmission.

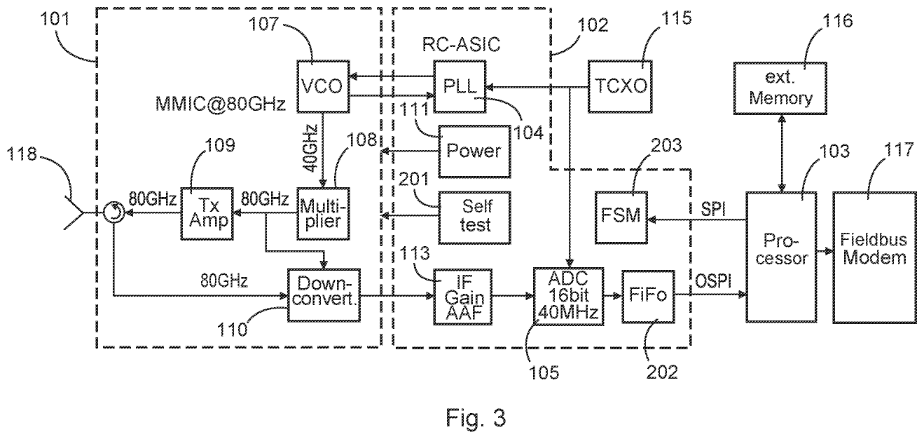

FIG. 2 shows a radar companion ASIC 102, which can perform control and detection tasks when operating a purely analog MMIC. The ASIC 102 has a linearization circuit, for example a integer or fractionally rational PLL 104, a power supply 111, a self-test circuit 201, an analogue amplification and filter circuit 113, an ADC circuit 105 (which is set up, for example, to convert analogue signals into digital values with an accuracy of 16 bits and a sampling frequency of 40 MHz), a first-in-first-out (FiFo) memory 202, and a finite state machine 203. The ASIC 102 is a separate component, but can be arranged on the same circuit board as the MMIC 101 (see FIG. 3).

FIG. 3 shows the structure of a radar circuit 100 for a radar measuring device, which has the ASIC 102 or radar companion ASIC 102 described above. The ASIC 102 is connected between the radar chip 101 and the processor 103. Communication between ASIC 102 and processor 103 takes place, for example, via the FiFo 202 by means of a quad serial peripheral interface (QSPI) and, starting from processor 103, via an SPI interface to FSM 203.

The ASIC 102 can supply the VCO 107 and the multiplier 108 of the MMIC 101 with energy and perform or trigger a self-test of the MMIC 101 (see FIG. 3). In particular, the RC-ASIC 102 can be used to check the function of the MMIC 101. This is particularly advantageous for SIL applications. It is possible that the processor 103 is integrated on the ASIC 102. However, it can also be a separate component, as shown in FIG. 3.

In particular, the MMIC 101 and the RC-ASIC 102 can be manufactured using different semiconductor technologies and chip materials. For example, the MMIC can be optimized for use at high frequencies, for example 80 GHz or above, whereas the RC-ASIC 102 is optimized for applications at significantly lower frequencies, for example 40 MHz. This can save energy or production costs compared to integrating the ASIC module on an MMIC.

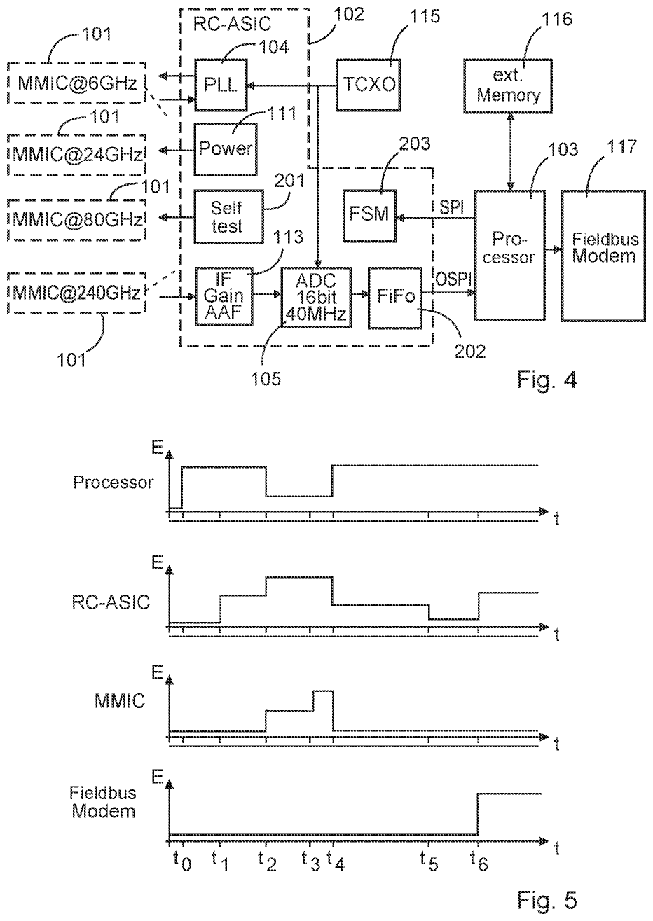

FIG. 4 shows the universal usability of the RC-ASIC 102 for radar MMICs for level measurement, which are designed for very different frequency ranges, for example for 6 GHz, 24 GHz, 80 GHz, 180 GHz, or 240 GHz.

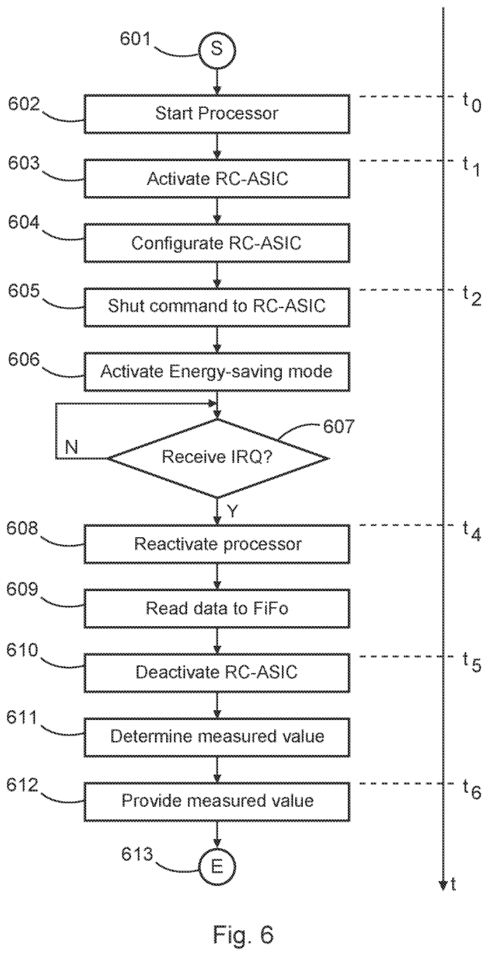

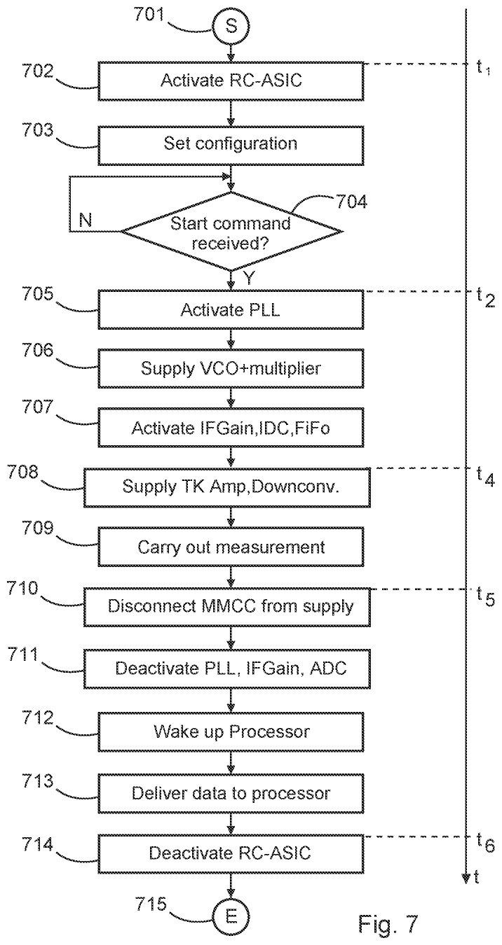

FIG. 5 shows a time sequence for the energy-optimized acquisition of measured values. Certain steps take place at the times t₁ to t₆, which are described below with reference to FIGS. 6 and 7.

The first diagram shows the energy consumed by the processor 103 over time. Initially, the processor is in sleep mode and is then woken up externally to start a new measurement run. After a period of increased energy demand (for example during an initialization phase of the processor), the energy demand decreases again and then increases again. The second diagram shows the energy requirement of the RC-ASIC 102 over time, which is woken up by the processor 103 at a specific time t₁ and has the highest energy requirement precisely in the period in which the energy requirement of the processor has fallen again.

The third diagram shows the energy requirement of the MMIC 101 over time, which has an increased energy requirement precisely when the processor has a low energy requirement.

And the last diagram shows the energy consumption of a fieldbus modem over time, which is used to transmit the measured values. The measured value transmission takes place at the end of a cycle when the MMIC is in sleep mode.

FIG. 6 shows an example of the states of the processor 103 during the energy-optimized acquisition of measured values. The process starts in step 601. The processor is started in step 602. This takes place at time t₀ (see also FIG. 5). At time t₁, the RC-ASIC is activated in step 603, which is then configured in step 604. In step 605, at time t₂, a start command is sent to the RC-ASIC and in step 606 the energy-saving mode of the processor is activated. In step 607, it is assessed whether the processor has received an interrupt request (IRQ) from the RC-ASIC.

If this is not the case, the system waits and then checks again whether an IRQ has been received from the RC-ASIC. If an IRQ has been received, step 608 takes place at time t₄, namely the reactivation of the processor, whereupon the processor reads data from the first-in-first-out memory of the RC-ASIC in step 609.

At time t₅, the RC-ASIC is deactivated in step 610, whereupon the processor determines the measured value from the data read out by the FiFo in step 611. At time t₆, the measured value is provided in step 612 and the process ends with step 613.

FIG. 7 shows an example of the states of a RC-ASIC during the energy-optimized acquisition of measured values. The procedure starts with step 701, whereupon the RC-ASIC is activated by the processor at time t₁ in step 702. In step 703, the configuration of the RC-ASIC is set under the control of the processor. For this purpose, specific operating parameters adapted to the respective connected MMIC are set, which may differ depending on the operating frequency of the connected MMIC. In step 704, it is determined whether the ASIC has received a start command. If this is not the case, the system waits and checks again whether a start command has been received. If this is the case, the PLL is activated in step 705 at time t₂. In step 706, the VCO and multiplier are supplied with power under the control of the RC-ASIC and in step 707 IF Gain, ADC and FiFo are activated and/or supplied with power by the RC-ASIC. At time t₃, the TX amplifier and the down converter are supplied and then the measurement is performed in step 709. It should be noted here that the times t₂, t₃, t₄, t₅ in particular should be determined depending on the MMIC connected in each case, whereby the RC-ASIC is set up to be able to implement the different times here. At time t₄, the MMIC is disconnected from the power supply under the control of the RC-ASIC and in step 711 the PLL, IF Gain and ADC are again deactivated or disconnected from the power supply by the RC-ASIC. In step 712, the processor is woken up again (by the RC-ASIC) and in step 713 the RC-ASIC supplies data to the processor. At time t₅, the RC-ASIC is deactivated in step 714. The procedure then continues with step 715.

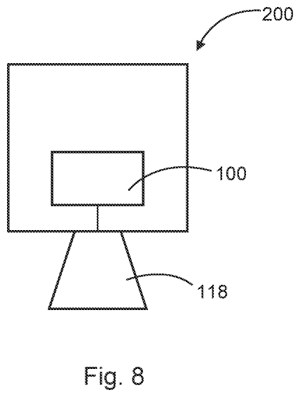

FIG. 8 shows a measuring device 200, for example a radar level measuring device, with the radar circuit 100 described above, which has a level radar antenna 118 for emitting the radar measuring signal and for receiving the radar measuring signal reflected at the product surface.

The terms used in the claims should be construed so as to give them the broadest reasonable interpretation consistent with the foregoing description. For example, the use of the article “a” or “the” when introducing an element should not be construed to exclude a plurality of elements. Similarly, the mention of “or” should be construed to include a plurality of elements, so that the mention of “A or B” does not exclude “A and B” unless it is clear from the context or the preceding description that only one of A and B is meant. Furthermore, the phrase “at least one of A, B, and C” should be understood as one or more of a group of elements consisting of A, B and C, and should not be interpreted as requiring at least one of each of the listed elements A, B, and C, regardless of whether A, B, and C are combined as categories or otherwise. In addition, the mention of “A, B, and/or C” or “at least one of A, B, or C” should be construed to include any single unit of the listed elements, e.g., A, any subset of the listed elements, e.g., A and B, or the entire list of elements A, B, and C.

1. A radar circuit for a measuring device, comprising:
a radar chip, configured to generate a radar measurement signal;
an application-specific integrated circuit (ASIC); and
a processor, configured to determine a measured value,
wherein the ASIC and the radar chip are separate components.

2. The radar circuit according to claim 1,
wherein the ASIC comprises a phase locked loop (PLL).

3. The radar circuit according to claim 1,
wherein the ASIC comprises an analog-to-digital converter (ADC) circuit.

4. The radar circuit according to claim 1,
wherein the ASIC has a digital interface to the processor.

5. The radar circuit according to claim 1,
wherein the ASIC has a finite state machine (FSM), which is configured to control the radar chip.

6. The radar circuit according to claim 1,
wherein the radar chip is a radar monolythic microwave integrated circuit (MMIC).

7. The radar circuit according to claim 1,
wherein the ASIC is a radar companion ASIC, which is configured to perform control tasks and/or measured value acquisition tasks in the radar circuit.

8. The radar circuit according to claim 1,
wherein the radar circuit is a level radar circuit for a level radar measuring device.

9. The radar circuit according to claim 1,
wherein the ASIC is configured to wake the processor from a sleep mode and thereupon transmit measurement data to the processor.

10. The radar circuit according to claim 1,
wherein the ASIC is configured to supply a voltage-controlled oscillator (VCO) of the radar chip and/or a multiplier of the radar chip.

11. An application-specific integrated circuit (ASIC) configured for a level radar measuring device, which comprises a radar chip, the ASIC and the radar chip being separate components.
